(19) United States
(12) Patent Application Publication
(10) Pub. No.: US 2006/0261372 A1
(43) Pub. Date: Nov. 23, 2006

(54) Heterojunction bipolar transistor and manufacturing method thereof

(75) Inventor: Akira Yoshioka, Yokohama-Shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/397,741

(22) Filed: Apr. 5, 2006

(30) Foreign Application Priority Data
Apr. 6, 2005 (JP) 2005-110193

(51) Int. Cl. H01L 31/00

(52) U.S. Cl. 257/197

(57) ABSTRACT

A heterojunction bipolar transistor in which an emitter area has an undoped layer including InGaAs, InAlAs or Inx (Ga_{y}Al_{1-y})₁₋ₓ As and a first conductivity-type partial emitter formed on a part of a surface of the undoped layer and including a material matched to the undoped layer; a first conductivity-type impurity concentration in the undoped layer is lower than the first conductivity-type impurity concentration of the partial emitter or the first conductivity-type impurity concentration in the undoped layer is 0; and at least sides of the partial emitter are covered by a metal protective layer while a part of the metal protective layer forms a Schottky junction with the undoped layer. The metal protective layer is formed by vacuum evaporation.

### CROSS-REFERENCE TO RELATED APPLICATION

This application is based upon and claims the benefit of priority from prior Japanese Patent Application No. 2005-110193, filed on Apr. 6, 2005, the entire contents of which are incorporated herein by reference.

### BACKGROUND OF THE INVENTION

1. Field of the Invention

The present invention relates to a heterojunction bipolar transistor and a manufacturing method thereof.

2. Background Art

Amid calls for increase in speed and capacity of a communication system nowadays, there is a need for development of electronic devices using III-V compound semiconductors, such as GaAs and InP. While there are the devices such as the MESFET and HEMT, using these compound semiconductors, a heterojunction bipolar transistor (HBT) among them is expected as an electronic device of superior performance such as high withstand voltage, low power consumption and integration in addition to its high-speed performance. Materials used to configure the HBT are the materials of a material system lattice-matched to GaAs (called a GaAs system) and the materials of a material system lattice-matched to InP (called an InP system for simplification). Of those, further high-speed performance can be expected as to the InP system materials in comparison with the GaAs system materials. The InP system materials are also expected to improve reliability to heat because of its high thermal conductivity. In particular, the devices using the InP system materials are effective in an optical communication system of which speed is 40 Gbps or higher while the InP system HBT is necessary for the devices requiring high withstand voltage such as a laser driver. The GaAs system materials also have an advantage of lower cost than the InP system materials.

As for manufacturing of the HBT using the InP and the HBT using the other compound semiconductors such as GaAs, an interface level of the compound semiconductor is higher than Si so that a process of forming a passivation film on a semiconductor element surface is essential. This film plays an important role of passivation of the interface level and also protection of the semiconductor from damage caused by oxidation and moisture. SiO₂, SiNₓ and the like are generally used for the passivation film. In general, the SiO₂ film and SiNₓ film are formed on the device by using a chemical vapor deposition method (CVD method). While the CVD method can be classified into various methods such as the one using plasma, a currently general method is the method of utilizing a chemical reaction occurred in a chamber of which temperature has risen to 250° C. or higher.

The InP system HBT of the past has a problem that reliability of a transistor is lowered by formation of the passivation film. Similar to this, a GaAs system HBT also has a problem that As breaks away from the surface, as a result the reliability of the transistor is a little lowered. These problems occur on the basis that the compound semiconductors such as the InP system materials and GaAs system materials are apt to be deteriorated by heat in comparison with Si.

However, it has been considered inevitable that a defect occurs on the surface of the compound semiconductor when the passivation film is formed. This is because it is extremely difficult to form the passivation film at a low temperature and it is very high-cost to form the passivation film by a different method from the past. This is also because it has been considered that there is no proper material for material, as another protective layer, to be provided between the surface of the compound semiconductor and the passivation film.

### SUMMARY OF THE INVENTION

An aspect of an embodiment of the present invention provides a heterojunction bipolar transistor including: a substrate; a first conductivity-type collector area formed on the substrate; a second conductivity-type base area formed on the collector area; and a first conductivity-type emitter area formed on the base area, the emitter area having: an undoped layer including InGaAs, InAlAs or Inx (Ga_{y}Al_{1-y}) ₁₋ₓ As; and a first conductivity-type partial emitter which is formed on a part of a surface of the undoped layer and which includes a material lattice-matched to the undoped layer, a first conductivity-type impurity concentration in the undoped layer being lower than the first conductivity-type impurity concentration of the partial emitter or the first conductivity-type impurity concentration in the undoped layer is 0; and at least sides of the partial emitter being covered by a metal protective layer while a part of the metal protective layer forming a Schottky junction with the undoped layer.

Another aspect of another embodiment of the present invention provides a method of manufacturing a heterojunction bipolar transistor which includes: a substrate; a first conductivity-type collector area formed on the substrate; a second conductivity-type base area formed on the collector area; and a first conductivity-type emitter area formed on the base area, the method comprising: processing a part of the emitter area to be a mesa-type partial emitter; and coverring mesa sides of the partial emitter by the metal protective layer formed by vacuum evaporation.

### BRIEF DESCRIPTION OF THE DRAWINGS

FIG. 1 is a sectional view showing a heterojunction bipolar transistor according to a first embodiment of the present invention;

FIG. 2 is a sectional view showing a method of manufacturing the heterojunction bipolar transistor according to the first embodiment of the present invention;

FIG. 3 is a sectional view subsequent to FIG. 2 showing the method of manufacturing the heterojunction bipolar transistor according to the first embodiment of the present invention;

FIG. 4 is a sectional view subsequent to FIG. 3 showing the method of manufacturing the heterojunction bipolar transistor according to the first embodiment of the present invention;

FIG. 5 is a sectional view subsequent to FIG. 4 showing the method of manufacturing the heterojunction bipolar transistor according to the first embodiment of the present invention;

FIG. 6 is a sectional view subsequent to FIG. 5 showing the method of manufacturing the heterojunction bipolar transistor according to the first embodiment of the present invention;

FIG. 7 is a sectional view subsequent to FIG. 6 showing the method of manufacturing the heterojunction bipolar transistor according to the first embodiment of the present invention;

FIG. 8 is a sectional view subsequent to FIG. 7 showing the method of manufacturing the heterojunction bipolar transistor according to the first embodiment of the present invention;

FIG. 9 is a sectional view subsequent to FIG. 8 showing the method of manufacturing the heterojunction bipolar transistor according to the first embodiment of the present invention;

FIG. 10 is a sectional view subsequent to FIG. 9 showing the method of manufacturing the heterojunction bipolar transistor according to the first embodiment of the present invention;

FIG. 11 is a sectional view showing a heterojunction bipolar transistor according to a second embodiment of the present invention; and

FIG. 12 is a sectional view showing a heterojunction bipolar transistor as a preceding embodiment of the present invention.

### DESCRIPTION OF THE EMBODIMENTS

First, a preceding embodiment known to the inventors hereof will be described.

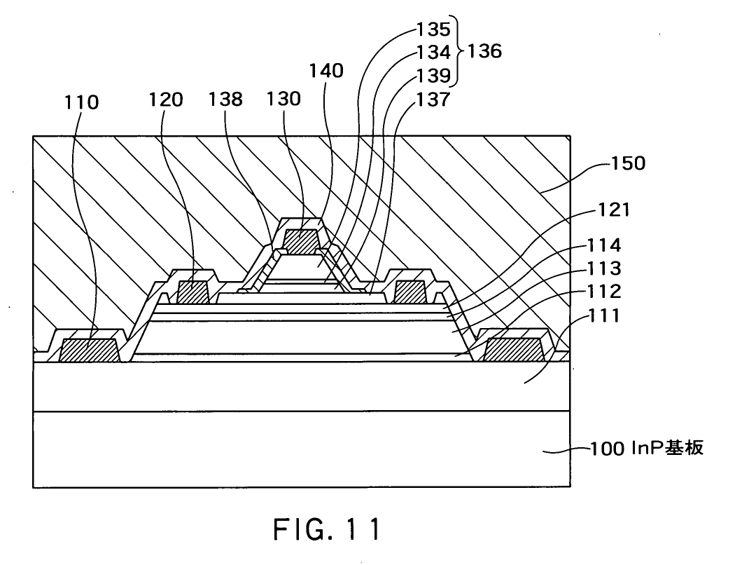

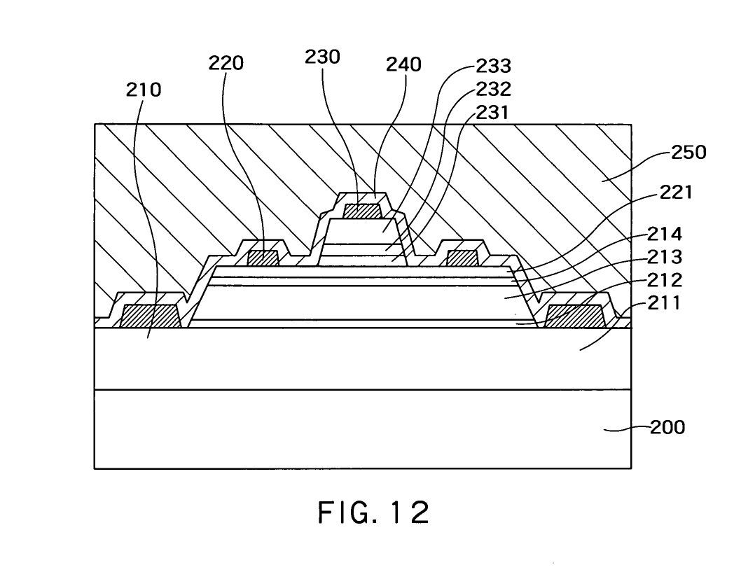

FIG. 12 is a diagram showing an InP system HBT. An Fe doped semi-insulating InP substrate 200 has an n-type InGaAs sub-collector layer 211 of which thickness is 300 nm and carrier concentration is 2E19 (cm⁻³), an n-type InP layer 212 of which thickness is 20 nm and carrier concentration is 5E18 (cm⁻³), an n-type InP collector layer 213 of which thickness is 350 nm and carrier concentration is 1E16 (cm⁻³) and an InGaAlAs layer 214 of which thickness is 50 nm sequentially formed thereon. Here, the InGaAlAs layer 214 is formed without using any dopant, where In composition is constant at 0.53 in the layer, and Ga composition and Al composition change linearly from 0.28 to 0.47 and from 0.19 to 0 from downside to topside in the drawing respectively. The layers 211 to 214 are a collector area. The collector area 211 to 214 has a base layer 221 composed of a p-type InGaAs of which thickness is 50 nm and carrier concentration is 3E19 (cm⁻³) formed thereon. The base layer 221 has an n-type InP emitter layer 231 of which thickness is 50 nm and carrier concentration is 3E17 (cm⁻³), an n-type InP layer 232 of which thickness is 50 nm and carrier concentration is 5E18 (cm⁻³) and an n-type InGaAs emitter contact layer 233 of which thickness is 200 nm and carrier concentration is 2E19 (cm⁻³) sequentially formed thereon. The layers 231 to 233 are an emitter area. The emitter area 231 to 233 is etched like a mesa as shown in FIG. 11. The emitter contact layer 233 of the emitter area 231 to 233 has an emitter metal 230 composed of Ti, Pt and Au formed thereon. The base layer 221 has a base metal 220 composed of Ti, Pt and Au formed thereon. The sub-collector layer 211 has a collector metal 210 composed of Ti, Pt and Au formed thereon. An element having the above semiconductor layers and metals are covered by a SiNₓ film (passivation film) 240. The SiNₓ film 240 is covered by polyimide 250.

The collector area 211 to 214, base layer 221 and emitter area 231 to 233 are put to epitaxial growth by using a metalorganic chemical vapor deposition method (MOCVD method) on the InP substrate 200. The mesa-like emitter area 231 to 233 is formed by using a compound liquid of H₃PO₄, H₂O₂ and H₂O or a compound liquid of HCl and H₂O as an etchant. The SiNₓ film 240 covering the element is deposited at 300° C. by using a plasma CVD method. The plasma CVD method is generally used as the deposition method of the SiNₓ film 240, and the SiNₓ film 240 is formed at low cost by this method.

As described above, the formation of the passivation film is an essential process as to the HBT using the compound semiconductors.

In the case of the above HBT, however, the high temperature, plasma and the like on forming the passivation film have an adverse effect on the surfaces of the compound semiconductors so that reliability of a transistor is lowered. As for the HBT using the InP system material shown in FIG. 12 in particular, the heat and plasma generated on deposition of the passivation film 240 causes P atoms to break away from a semiconductor surface and generate a defect on a crystal surface so as to deteriorate device properties such as a current gain and reverse withstand voltage of a base collector diode. To be more precise, when depositing the SiNₓ film 240 by the plasma CVD method on the device of FIG. 12, the P atoms break away from the surface due to the plasma and generate a defect on the crystal surface on a side of the n-type InP emitter layer 231 exposed on the side of the emitter mesa 231 to 233. And a level generated by this defect lowers the current gain of the transistor. The defect due to the plasma deteriorates the base collector diode withstand voltage.

An embodiment having improved the preceding embodiment will be described.

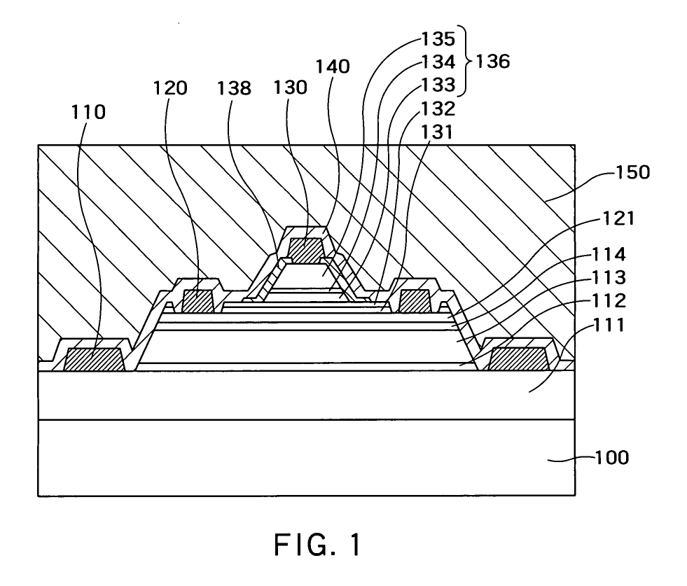

To be more specific, the bipolar transistor according to the embodiment of the present invention will be described. As shown in FIG. 1 for instance, one of the characteristics of the bipolar transistor according to this embodiment is that, in the InP system HBT, an emitter area 131 to 135 includes an undoped InGaAs layer 132, an emitter mesa (mesa structure portion) 136 formed on a part of the surface of the undoped InGaAs layer 132, and the sides of the emitter mesa 136 are covered by an Mo (molybdenum) protective layer 138. As for this transistor, heat resistance of the Mo protective layer 138 is so good that crystallization on the sides of the emitter mesa 136 does not deteriorate on forming a SiNₓ film 140 and so the reliability can be improved. The Mo protective layer 138 and the undoped InGaAs layer 132 form a Schottky junction. Therefore, in spite of using conductive Mo for the protective layer, no short-circuit of the protective layer occurs and so electric properties do not deteriorate.

Hereunder, two embodiments will be described.

### First Embodiment

FIG. 1 is a sectional view showing a heterojunction bipolar transistor according to a first embodiment of the present invention. An Fe doped semi-insulating InP substrate 100 has an n-type InGaAs sub-collector layer 111 of which thickness is 300 nm and carrier concentration is 2E19 (cm⁻³), an n-type InP layer 112 of which thickness is 20 nm and carrier concentration is 5E18 (cm⁻³), an n-type InP collector layer 113 of which thickness is 350 nm and carrier concentration is 1E16 (cm⁻³) and an InGaAlAs layer 114 of which thickness is 50 nm sequentially formed thereon. Here, the InGaAlAs layer 114 is formed without using any dopant, where In composition is constant at 0.53 in the layer, and Ga composition and Al composition change linearly from 0.28 to 0.47 and from 0.19 to 0 from downside to topside in the drawing respectively. The layers 111 to 114 are a collector area. The collector area 111 to 114 has a base layer (base area) 121 composed of a p-type InGaAs of which thickness is 50 nm and carrier concentration is 3E19 (cm⁻³) formed thereon. The p-type InGaAs base layer 121 has an n-type InP first emitter layer 131 of which thickness is 18 nm and carrier concentration is 3E17 (cm⁻³), an undoped InGaAs layer 132 of which thickness is 7 nm and formed without using any dopant, an n-type InP second emitter layer 133 of which thickness is 50 nm and carrier concentration is 3E17 (cm⁻³), an n-type InP emitter contact layer 134 of which thickness is 50 nm and carrier concentration is 5E18 (cm⁻³) and an n-type InGaAs emitter contact layer 135 of which thickness is 100 nm and carrier concentration is 2E19 (cm⁻³) sequentially formed thereon. The layers 131 to 135 are an emitter area. The emitter area 131 to 135 has a structure having the undoped InGaAs layer 132 and the n-type emitter mesa (partial emitter) 136 which is formed like a mesa on a part of the surface of the undoped layer 132, made of a material lattice-matched to the undoped layer 132 and has a higher n-type impurity concentration than the undoped layer. Here, the lattice-matched material is a material having lattice mismatch of 1 percent or less. If the lattice mismatch is 1 percent or less, a crystal of easy crystal growth and good crystallinity is formed.

One of the characteristics of the transistor of FIG. 1 is that the Mo (molybdenum) protective layer 138 is formed at least on the sides of the emitter mesa 136. To be more specific, the Mo (molybdenum) layer 138 is formed on the sides of the emitter mesa 136 and the area surrounding the emitter mesa 136 out of the surface of the undoped layer 132. As will be described later, the Mo protective layer 138 forms the Schottky junction with the undoped layer 132 and is formable by vacuum evaporation. The undoped layer 132 is a layer formed without using any dopant, and is not limited to a complete intrinsic semiconductor but also includes a layer indicating a weak n-type due to diffusion of n-type impurities and the like. However, the n-type impurity concentration of the undoped layer 132 is lower than that of the emitter mesa 136.

The emitter contact layer 135 of the emitter layers 131 to 135 has an emitter metal 130 composed of Ti, Pt and Au formed thereon. The base layer 121 has a base metal 120 composed of Ti, Pt and Au formed thereon. The sub-collector layer 111 has a collector metal 110 composed of Ti, Pt and Au formed thereon. An element having the above semiconductor layers and metals is covered by a SiNₓ film (passivation film) 140. The SiNₓ film 140 is covered by a polyimide 150 for protection.

The transistor of FIG. 1 is an npn-type heterojunction bipolar transistor including the n-type collector area 111 to 114, p-type base area 121 and n-type emitter area 131 to 135. As with an ordinary bipolar transistor, this transistor is used by applying a voltage to the collector metal 110, base metal 120 and emitter metal 130.

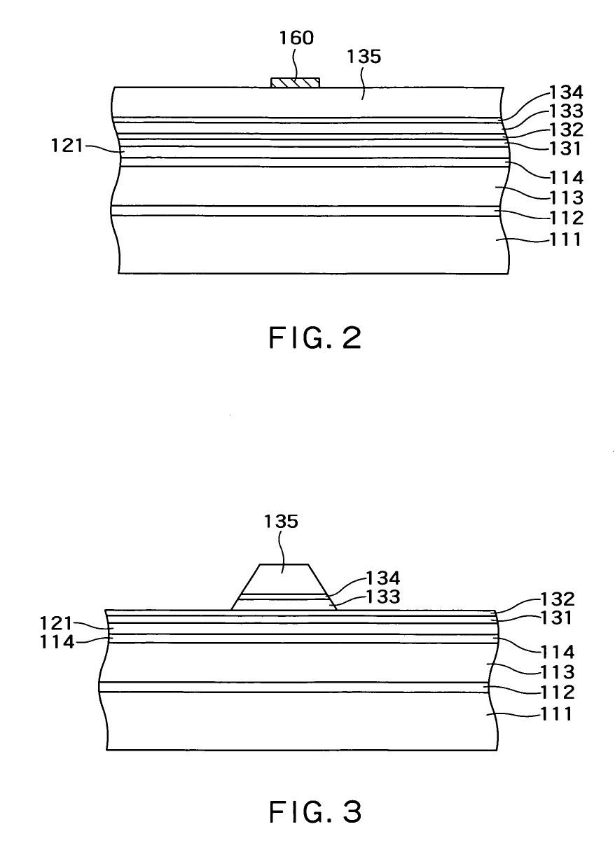

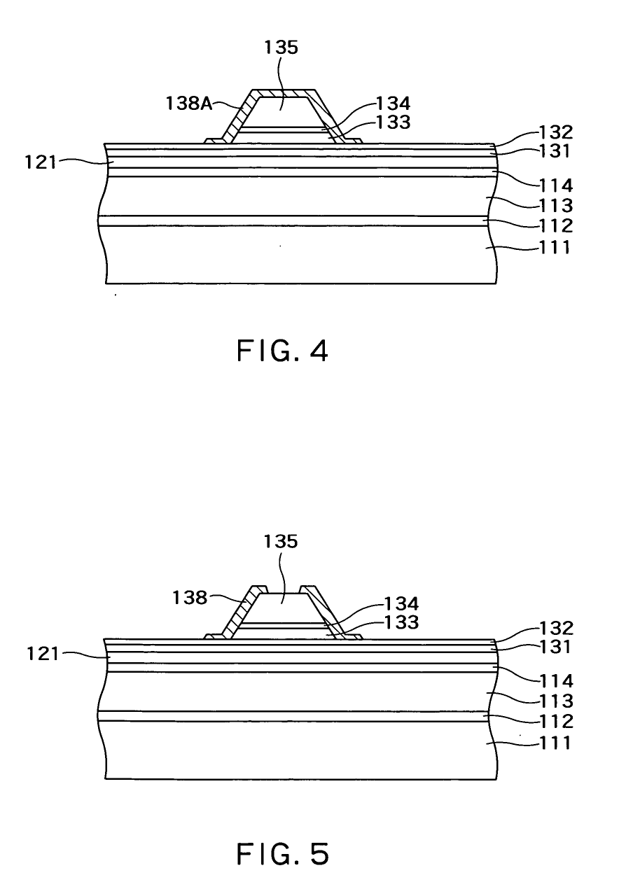

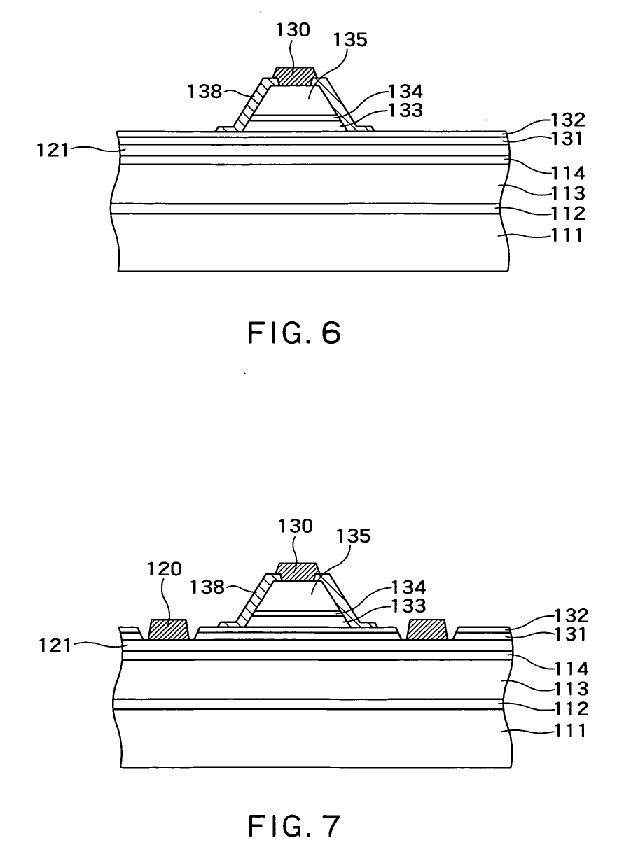

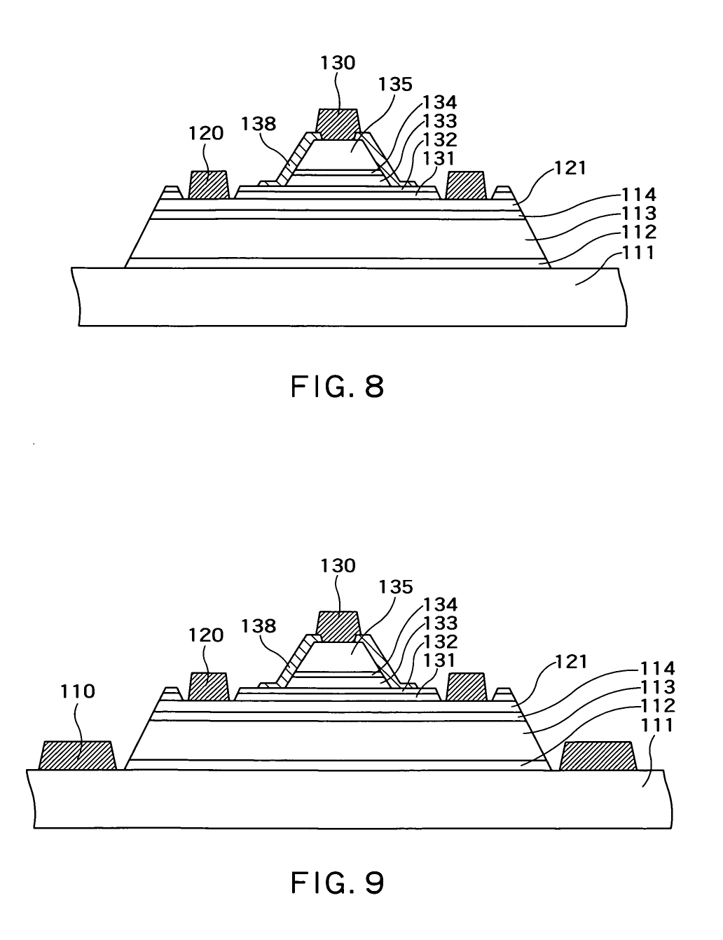

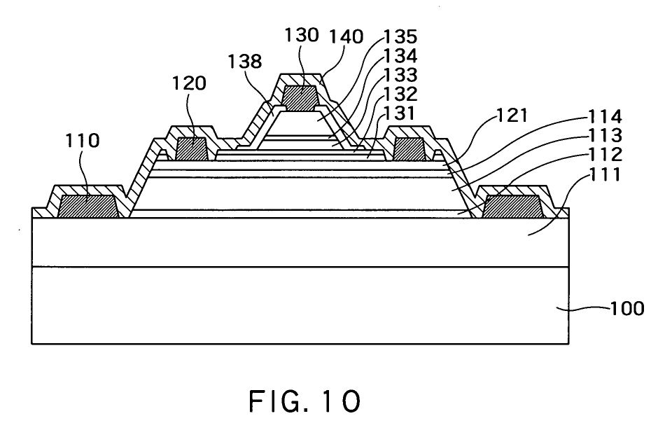

Next, a method of manufacturing the transistor of FIG. 1 will be described by referring to FIGS. 2 to 10. One of the characteristics of this manufacturing method is that the Mo protective layer 138 shown in FIG. 5 is formed by vacuum evaporation. As the vacuum evaporation can be performed at a low substrate temperature of about 30° C., it can prevent the semiconductor surface of the mesa structure portion 136 from deteriorating due to a high temperature. FIGS. 2 to 9 show simplified diagrams of the InP substrate 100 of FIG. 1.
(1) First, as shown in FIG. 2, the metalorganic chemical vapor deposition method (MOCVD method) is used to sequentially form the n-type InGaAs sub-collector layer 111, n-type InP layer 112, n-type InP collector layer 113, InGaAlAs layer 214, p-type InGaAs base layer 121, n-type InP first emitter layer 131, undoped InGaAs layer 132, n-type InP second emitter layer 133, n-type InP emitter contact layer 134 and n-type InGaAs emitter contact layer 135 on the InP substrate 100 (refer to FIG. 1). All these layers are matched to the InP substrate. In this epitaxial growth, all the n-type dopants use Si, and a p-type dopant of the base layer 121 uses carbon. The undoped InGaAs layer 132 is formed without using these dopants. Subsequently, on the epitaxial wafer, an existing lithographical technique using a reverse taper resist is used to mask it except the emitter area with the resist, and then an etching mask 160 composed of Ti (titanium) is formed by the vacuum evaporation and liftoff technology as shown in FIG. 2.
(2) Next, as shown in FIG. 3, the n-type InGaAs emitter contact layer 135 is etched by using the compound liquid of H₃PO₄, H₂O₂ and H₂O as the etchant. Subsequently, the n-type InP emitter contact layer 134 and n-type InP second emitter layer 133 are sequentially etched by using the compound liquid of HCl and H₂O as the etchant. Subsequently, the etching mask 160 (refer to FIG. 2) is etched by using an NH₄F solution as the etchant to form the emitter mesa as shown in FIG. 3.
(3) Next, as is understandable from FIG. 4, the lithographical technique using the reverse taper resist is used to form a mask on the portion except the area surrounding the emitter structure portions 133 to 135 of the surface of the undoped InGaAs layer 132. And a mesa side protective layer 138A shown in FIG. 4 is formed by using this mask and also using the existing (heretofore known) vacuum evaporation and liftoff technology. The mesa side protective layer 138A is composed of molybdenum of which thickness is 50 nm. The substrate temperature in the vacuum evaporation is approximately 30° C.
(4) Next, the existing lithographical technique is used to mask it except an emitter metal area for forming the emitter metal 130 (refer to FIG. 1). As shown in FIG. 5, a part of the mesa side protective layer 138A is etched by using an RIE apparatus so as to open the emitter metal area. The mesa side protective layer 138A having the emitter metal area opened becomes the Mo protective layer 138.
(5) Next, the existing lithographical technique using the reverse taper resist is used to mask it except the emitter metal area. As shown in FIG. 6, the emitter metal 130 composed of Ti, Pt and Au is formed in the emitter metal area by using the existing vacuum evaporation and liftoff technology.
(6) Next, the existing lithographical technique using the reverse taper resist is used to open the resist on a base metal forming area. As shown in FIG. 7, the InGaAs layer 132 is etched by using the compound liquid of H₃PO₄, H₂O₂ and H₂O as the etchant. Subsequently, the InP first emitter layer 131 is etched by using the compound liquid of HCl and H₂O as the etchant so as to expose the surface of the base layer 121 in the base metal area. Thereafter, the base metal 120 composed of Ti, Pt and Au is formed by the existing vacuum evaporation and liftoff technology.
(7) Next, a predetermined area is masked by the existing lithographic technique, and then, as is understandable from FIG. 8, the InGaAs layer 132 in the right and left portions of FIG. 7 is etched by using the compound liquid of H₃PO₄, H₂O₂ and H₂O as the etchant. Subsequently, as is understandable from FIG. 8, the InP first emitter layer 131 in the right and left portions of the drawing is etched by using the compound liquid of HCl and H₂O as the etchant. Subsequently, the p-type InGaAs base layer 121 and undoped InGaAlAs setback layer 114 in the right and left portions of the drawing are etched by using the compound liquid of H₃PO₄, H₂O₂ and H₂O as the etchant, and the n-type InP collector layer 113 and n-type InP collector contact layer 112 in the right and left portions of the drawing are etched by using the compound liquid of HCl and H₂O as the etchant sequentially so as to form a collector mesa.
(8) Next, the existing lithographical technique using the reverse taper resist is used to mask it except the collector metal forming area. Thereafter, the collector metal 110 composed of Ti, Pt and Au is formed by the existing vacuum evaporation and liftoff technology as shown in FIG. 9. Subsequently, the transistor area is masked by the existing lithographical technique. Thereafter, the n-type InGaAs sub-collector layer 111 is etched by using the etchant composed of the compound liquid of H₃PO₄, H₂O₂ and H₂O, and the InP substrate 100 (refer to FIG. 1) is etched to an appropriate depth by using the etchant composed of the compound liquid of HCl and H₂O so as to perform device isolation by the mesa.
(9) Next, as shown in FIG. 10, the SiNₓ film (passivation film) 140 is deposited at 300° C. by using the plasma CVD method. Thereafter, the photosensitive polyimide 150 is applied, exposure and development are performed and final hardening of the photosensitive polyimide 150 is performed in an oven at 320° C. to complete the transistor shown in FIG. 1. In the case of integrated circuits and the like, a wiring process, a passive element formation process of resistances, capacitors and the like are further added. However, existing processes may be used as to those.

As for the heterojunction bipolar transistor of FIG. 1 manufactured by the manufacturing method described above, it is possible, as the passivation film 140 composed of SiNₓ is provided, to protect the semiconductor from the damage caused by oxidation and moisture and extend life of the transistor.

The heterojunction bipolar transistor of FIG. 1 has the sides of the emitter mesa 136 covered by the Mo protective layer 138. The Mo configuring the Mo protective layer 138 is a metal and is highly heat-resistant. For this reason, the transistor of FIG. 1 can prevent the P atoms from breaking away from the surface of the sides of the InP layers 133 and 134 when forming the passivation film 140 at a high temperature of 300° C. or so. Consequently, the transistor of FIG. 1 can prevent a crystal defect from occurring on the surface of the sides of the InP layers 133 and 134 so as to improve the reliability.

The heterojunction bipolar transistor of FIG. 1 has the Mo protective layer 138 formed by the vacuum evaporation at a low temperature of 30° C. or so. Therefore, the defect seldom occurs on the surface of the sides of the InP layers 133 and 134 when forming the Mo protective layer 138.

The heterojunction bipolar transistor of FIG. 1 has the Schottky junction formed by the Mo protective layer 138 and the undoped InGaAs layer 132, and has a reverse bias applied to the Mo protective layer 138 and the InGaAs layer 132 in use. Because of the Schottky junction, a current flowing from the emitter metal 130 to the InGaAs layer 132 via the Mo protective layer 138 almost becomes zero. To be more specific, the transistor of FIG. 1 is provided with the Schottky junction so that the Mo protective layer 138 can prevent the short-circuit between the emitter metal 130 and the InGaAs layer 132. In addition, the transistor of FIG. 1 has the InGaAs layer 132 rendered undoped, and so a Schottky barrier formed on the InGaAs layer 132 can be raised to further prevent the short-circuit. For this reason, the transistor of FIG. 1 seldom has its electric properties deteriorated due to the short-circuit in spite of using a conductive Mo for the Mo protective layer 138.

However, it is probably against common sense of an ordinary engineer to provide the conductive Mo protective layer 138 and further provide the undoped InGaAs layer 132 as in FIG. 1. This is because the ordinary engineer thinks that if the undoped layer 138 of a low carrier concentration is provided, the current passes less smoothly and the electric properties deteriorate. It is also because, if the InGaAs layer 132 is doped with the n-type impurities to avoid the deterioration of electric properties, the Schottky barrier is lowered and the short-circuit is apt to occur. According to an experiment of the inventors hereof, however, the transistor of FIG. 1 could maintain the electric properties as much as the transistor of the past and still improve the reliability. The inventors hereof think that it is because a merit of having the crystal defect of the InP layers 133 and 134 reduced by the Mo protective layer 138 and a merit of preventing the short-circuit of the Mo protective layer 138 overtake a demerit of providing the layer 132 of a low carrier concentration.

The transistor of FIG. 1 can form the passivation film 140 by the same method as that of the past. For this reason, the transistor of FIG. 1 has almost no increase in cost in comparison with those of the past. The Mo configuring the protective layer 138 is generally used as an electrode material, and is low-cost. For this reason, the cost is hardly increased by newly providing the Mo protective layer 138.

As described above, it is possible, according to the heterojunction bipolar transistor of FIG. 1, to provide the transistor of high reliability and low cost.

Next, the material of the Mo protective layer 138 is considered. To be more specific, as for the heterojunction bipolar transistor of FIG. 1, the material of the protective layer 138 is Mo. However, the material of the protective layer 138 can be a material other than Mo if capable of forming the Schottky junction with the undoped InGaAs layer 132 and formable by the vacuum evaporation. Such a material can be Ti (titanium), Al (aluminum), Au (gold), Pt (platinum), Ni (nickel) or a Pd (palladium) in terms of its physicality. Thus, the material is considered.

First, in the case of using Ti for the protective layer 138, almost the same good properties as in the case of using Mo are obtained according to the experiment of the inventors hereof. However, the properties are a little more variable than in the case of using Mo. This is supposedly because the diffusion of Ti is a little more significant. The substrate temperature in the vacuum evaporation can be approximately 30° C. as in the case of Mo.

Next, a good result cannot be obtained in the case of using Al. To be more precise, in the case of the vacuum evaporation using an electronic beam, a good Schottky junction cannot be obtained because ionized Al hits and damages the semiconductor surface. It is difficult to use resistance overheating in practice because it causes a reaction to a board for placing an Al ingot on.

Next, in the case of Au, Pt, Ni and Pd, the Schottky junction is obtained but the properties are not as good as those in the case of using Mo or Ti. This is supposedly because alloying of Au, Pt, Ni and Pd and the semiconductor starts at a relatively low temperature (300° C. to 400° C.) and as the undoped InGaAs layer 132 is thin, functions of the undoped InGaAs layer 132 are significantly lowered once the alloying of the undoped InGaAs layer 132 and the protective layer 138 occurs.

As described above, the material of the protective layer 138 should be Mo, Ti, Au, Pt, Ni and Pd, or preferably Mo and Ti or more preferably Mo.

The heterojunction bipolar transistor of FIG. 1 described above has the emitter mesa 136 in a form of a forward mesa. It becomes easier, by having it in the form of the forward mesa, to form the protective layer 138 by the vacuum evaporation. To describe it in detail, it becomes easier to form the protective layer 138 by setting an angle of a vertical mesa at 90° while setting the angle of the forward mesa at 45° or more or preferably 60° or more. Inversely, if a mesa section is a backward mesa, it becomes difficult to form the protective layer 138. For this reason, it is possible, in the case of the integrated circuits or the like, to render the emitter long and thin and render a side of the forward mesa as in FIG. 1 relatively longer so as to have more significant effects.

### Second Embodiment

The heterojunction bipolar transistor of a second embodiment is different from the first embodiment (FIG. 1) in that, as shown in FIG. 11, the undoped InGaAs layer 132 (FIG. 1) is replaced by an undoped InAlAs layer 137 to eliminate the n-type InP first emitter layer 131. The other configurations are the same as the first embodiment, and the same portions as the first embodiment are indicated by the same symbols. The n-type InP second emitter layer 133 (FIG. 1) and an n-type InP emitter layer 139 (FIG. 11) are substantially the same layer although their names are different.

The heterojunction bipolar transistor of FIG. 11 is provided with the protective layer 138 so as to provide a high-reliability transistor as with the first embodiment. As the SiNₓ film 140 is formed by the same generally used method as that of the past, it is possible to provide a low-cost transistor.

The heterojunction bipolar transistor of FIG. 11 has a band gap of the undoped InAlAs layer 137 wider than the band gap of the undoped InGaAs layer 132 (FIG. 1). For this reason, it is possible to increase a band gap difference between the base layer 121 and the undoped layer and thereby further increase the amplification factor and speed of the transistor.

The heterojunction bipolar transistor of FIG. 11 is not provided with the first emitter area 131 (FIG. 1), and so it is possible to simplify the crystal growth and etching process.

If electrons tunnel through the undoped layer 137, however, the undoped layer 137 no longer functions and the electric properties deteriorate significantly because the heterojunction bipolar transistor of FIG. 11 is not provided with the first emitter layer 131 (FIG. 1). For this reason, the thickness of the undoped layer 137 of the transistor of FIG. 11 should desirably be 10 nm or more.

According to the embodiment described above, a description was given as to an example of rendering the undoped layers 132 and 137 as InₓGa₁₋ₓAs (0≦x≦1) or InₓAl₁₋ₓAs (0≦x≦1). However, this may also be Inₓ (Ga_{y}Al_{1-y}) ₁₋ₓAs (0≦x≦1, 0≦y≦1). Even in the case where the undoped layer 132 is rendered as Inₓ (Ga_{y}Al_{1-y}) ₁₋ₓAs (0≦x≦1, 0≦y≦1), Mo and Ti can be used desirably as the material of the protective layer 138.

The heterojunction bipolar transistor of this embodiment can have the n-type (first conductivity type) and the p-type (second conductivity type) reversed.

This embodiment also described the example of forming the undoped Inₓ (Ga_{y}Al_{1-y}) ₁₋ₓAs layers 132 and 137 and the protective layer 138 on the InP system HBT using the InP substrate 100. However, the undoped Inₓ (Ga_{y}Al_{1-y}) ₁₋ₓAs layers and the protective layer of this embodiment may also be used for a GaAs system HBT using a GaAs substrate. In the case of the GaAs system HBT, there are also the cases where As breaks away from the semiconductor surface on forming the passivation film, and so the reliability can be improved by providing the protective layer as that of this embodiment. As for the GaAs system HBT, the material of the protective layer should also desirably be Mo or Ti.

According to the embodiments of the present invention, it is possible to provide the heterojunction bipolar transistor of high reliability and low cost.

1. A heterojunction bipolar transistor comprising:
a substrate;
a first conductivity-type collector area formed on the substrate;
a second conductivity-type base area formed on the collector area; and
a first conductivity-type emitter area formed on the base area,
the emitter area having:
an undoped layer including InGaAs, InAlAs or Inₓ (Ga_{y}Al_{1-y}) ₁₋ₓ As; and
a first conductivity-type partial emitter which is formed on a part of a surface of the undoped layer and which includes a material lattice-matched to the undoped layer,
a first conductivity-type impurity concentration in the undoped layer being lower than the first conductivity-type impurity concentration of the partial emitter or the first conductivity-type impurity concentration in the undoped layer is 0; and
at least sides of the partial emitter being covered by a metal protective layer while a part of the metal protective layer forming a Schottky junction with the undoped layer.

2. The heterojunction bipolar transistor according to claim 1, wherein the partial emitter is configured in a form of a mesa.

3. The heterojunction bipolar transistor according to claim 1, wherein the undoped layer is configured by including InₓGa₁₋ₓAs (0≦x≦1), InₓAl₁₋ₓAs (0≦x≦1) or Inₓ (Ga_{y}Al_{1-y}) ₁₋ₓAs (0≦x≦1, 0≦y≦1).

4. The heterojunction bipolar transistor according to claim 1, wherein the metal protective layer includes a material formable by vacuum evaporation.

5. The heterojunction bipolar transistor according to claim 1, wherein the sides of the partial emitter and a part of a surface of the undoped layer are covered by the metal protective layer.

6. The heterojunction bipolar transistor according to claim 1, wherein the metal protective layer includes Mo, Ti, Au, Pt, Ni or Pd.

7. The heterojunction bipolar transistor according to claim 1, wherein at least the metal protective layer is covered by a passivation film.

8. The heterojunction bipolar transistor according to claim 1, wherein the substrate is an InP substrate and the partial emitter has an emitter layer including Inp.

9. The heterojunction bipolar transistor according to claim 1, wherein:
the collector area includes an InGaAlAs layer; and
the InGaAlAs layer has an In composition constant in a thickness direction, a Ga composition increasing from the substrate side to the base area direction in the thickness direction, and an Al composition decreasing from the substrate side to the base area in the thickness direction.

10. The heterojunction bipolar transistor according to claim 1, wherein the undoped layer is in contact with the base area via a first conductivity-type InP layer as a part of the emitter area.

11. The heterojunction bipolar transistor according to claim 10, wherein the undoped layer includes InₓGa₁₋ₓAs (0≦x≦1) or Inₓ (Ga_{y}Al_{1-y}) ₁₋ₓAs (0≦x≦1, 0≦y≦1).

12. The heterojunction bipolar transistor according to claim 1, wherein the undoped layer is in direct contact with the base area.

13. The heterojunction bipolar transistor according to claim 12, wherein the undoped layer includes InₓAl₁₋ₓAs (0≦x≦1) or Inₓ (Ga_{y}Al_{1-y}) ₁₋ₓAs (0≦x≦1, 0≦y≦1).

14. The heterojunction bipolar transistor according to claim 7, wherein an emitter electrode, a base electrode and a collector electrode are formed on the emitter area, the base area and the collector area respectively; and these electrodes and the metal protective layer are covered by the passivation film.

15. The heterojunction bipolar transistor according to claim 14, wherein a polyimide for protection is formed on the passivation film.

16. The heterojunction bipolar transistor according to claim 1, wherein the substrate is an InP substrate or a GaAs substrate.

17. A method of manufacturing a heterojunction bipolar transistor which includes:
a substrate;
a first conductivity-type collector area formed on the substrate;
a second conductivity-type base area formed on the collector area; and
a first conductivity-type emitter area formed on the base area, the method comprising:
processing a part of the emitter area to be a mesa-type partial emitter; and
coverring mesa sides of the partial emitter by the metal protective layer formed by vacuum evaporation.

18. The method of manufacturing a heterojunction bipolar transistor according to claim 17, wherein Mo, Ti, Au, Pt, Ni or Pd is used as a material of the metal protective layer.

19. The method of manufacturing a heterojunction bipolar transistor according to claim 17, wherein the vacuum evaporation is performed with a temperature of the substrate being about 30° C.

20. The method of manufacturing a heterojunction bipolar transistor according to claim 17, wherein the heterojunction bipolar transistor is formed so that:
the emitter area has an undoped layer including InGaAs, InAlAs or Inₓ (Ga_{y}Al_{1-y}) ₁₋ₓ As and a first conductivity-type partial emitter formed on a part of a surface of the undoped layer and including a material lattice-matched to the undoped layer; and
a first conductivity-type impurity concentration in the undoped layer is lower than the first conductivity-type impurity concentration of the partial emitter or the first conductivity-type impurity concentration in the undoped layer is 0.
